(19) United States
(12) Patent Application Publication
(10) Pub. No.: US 2016/0126356 A1
(43) Pub. Date: May 5, 2016

(54) ACTIVE DEVICE CIRCUIT SUBSTRATE

(71) Applicant: E Ink Holdings Inc., Hsinchu (TW)

(72) Inventors: Cheng-Hang Hsu, Hsinchu (TW); Tzung-Wei Yu, Hsinchu (TW); Yu-Lin Hsu, Hsinchu (TW); Ted-Hong Shinn, Hsinchu (TW)

(21) Appl. No.: 14/819,434

(22) Filed: Aug. 6, 2015

(30) Foreign Application Priority Data
Oct. 30, 2014 (TW) 103137592

(51) Int. Cl. H01L 29/786; H01L 29/417; H01L 27/12

(52) U.S. Cl. CPC H01L 29/7869; H01L 27/1225; H01L 27/1248; H01L 29/41733

(57) ABSTRACT

An active device circuit substrate includes a substrate, a plurality of active devices, and a first planarization layer. Each active device includes a gate electrode, a channel layer stacked with the gate electrode, a source electrode, and a drain electrode. The source electrode and the drain electrode are disposed on the channel layer and located on opposite sides of the channel layer to define a channel area of the channel layer. The active devices include a first active device and a second active device. The first active device is disposed between the first planarization layer and the substrate, and the first planarization layer is disposed between the first active device and the second active device. A minimum linear distance between the channel area of the first active device and the channel area of the second active device along a direction parallel to the substrate is not smaller than 5 μm.

### CROSS-REFERENCE TO RELATED APPLICATION

This application claims the priority benefit of Taiwan application serial no. 103137592, filed on Oct. 30, 2014. The entirety of the above-mentioned patent application is hereby incorporated by reference herein and made a part of this specification.

### BACKGROUND OF THE DISCLOSURE

1. Field of the Invention

The invention relates to a circuit substrate, and more particularly to an active device circuit substrate.

2. Description of Related Art

An amorphous silicon (a-Si) thin film transistor (TFT) or a low-temperature polysilicon TFT is usually adopted in a conventional active device circuit substrate as a switching device. However, with the progress of technology, research has pointed out that an oxide semiconductor TFT has higher mobility than the a-Si TFT and further has more preferable uniformity in threshold voltage (Vth) than the low-temperature polysilicon TFT. Therefore, the oxide semiconductor TFT has the potential of becoming a key device in the next generation of active device circuit substrates. However, currently limited by the lithography capabilities in large areas, the oxide semiconductor TFT still has difficulty in integration, which restricts the scope of application thereof, such as application to logic devices.

### SUMMARY OF THE INVENTION

The invention is directed to an active device circuit substrate capable of providing an integrated active device.

An active device circuit substrate of the invention includes a substrate, a plurality of active devices, and a first planarization layer. The active devices are disposed on the substrate. Each of the active devices includes a gate electrode, a channel layer, a source electrode, and a drain electrode. The channel layer is stacked with the gate electrode. The source electrode and the drain electrode are disposed on the channel layer and located on opposite sides of the channel layer, so as to define a channel area of the channel layer. The first planarization layer is disposed on the substrate, wherein the active devices include at least one first active device and at least one second active device. The first active device is disposed between the first planarization layer and the substrate, and the first planarization layer is disposed between the first active device and the second active device. A minimum linear distance between the channel area of the first active device and the channel area of the second active device along a direction parallel to the substrate is larger than or equal to 5 μm.

In an embodiment of the invention, the channel layer of each of the active devices is an oxide semiconductor layer.

In an embodiment of the invention, the first planarization layer is an organic material layer, a silicon-based material layer, a mixed layer of an organic material and a silicon-based material, or a stacked layer of at least two of the above layers.

In an embodiment of the invention, a thickness of the first planarization layer is 0.5 μm to 5 μm.

In an embodiment of the invention, the first planarization layer includes at least one through hole, and the second active device is electrically connected to the first active device via the through hole.

In an embodiment of the invention, the at least one second active device is electrically insulated from the at least one first active device via the first planarization layer.

In an embodiment of the invention, the active device circuit substrate further includes a first protective layer, wherein the second active device is disposed between the first protective layer and the first planarization layer.

In an embodiment of the invention, the first protective layer is an inorganic material layer.

In an embodiment of the invention, the active device circuit substrate further includes a second planarization layer, wherein the first protective layer is disposed between the second active layer and the second planarization layer.

In an embodiment of the invention, the active device circuit substrate further includes a second protective layer. The second protective layer is disposed between the first planarization layer and the first active device.

In an embodiment of the invention, the source electrode and the drain electrode of the first active device are arranged in a direction perpendicular to a direction that the first active device is arranged, and the source electrode and the drain electrode of the second active device are arranged in a direction perpendicular to a direction that the second active device is arranged.

In an embodiment of the invention, the source electrode and the drain electrode of the first active device are arranged in a direction parallel to a direction that the first active device is arranged, and the source electrode and the drain electrode of the second active device are arranged in a direction parallel to a direction that the second active device is arranged.

In an embodiment of the invention, the source electrode and the drain electrode of the first active device are arranged in a direction that is neither parallel nor perpendicular to a direction that the first active device is arranged, and the source electrode and the drain electrode of the second active device are arranged in a direction that is neither parallel nor perpendicular to a direction that the second active device is arranged.

Based on the above, integration of the active device is facilitated by disposing the first and second active devices on opposite sides of the first planarization layer in the active device circuit substrate in the embodiments of the invention. In addition, simultaneously with the integration, it is ensured that the second active device is formed on a relatively flat area of the first planarization layer by controlling the minimum horizontal distance between the second active device and the first active device, so as to enhance the reliability of the second active device.

To make the above features and advantages of the present disclosure more comprehensible, several embodiments accompanied with drawings are described in detail as follows.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-section view of an active device circuit substrate according to the first embodiment of the invention.

FIGS. 2A to 2C are schematic top views of three examples of relative positions of a channel layer, a source electrode and a drain electrode in FIG. 1.

FIGS. 3A to 3C are schematic top views of three examples of relative positions of a first active device and a second active device in FIG. 1.

FIGS. 4 to 6 are schematic cross-section views of an active device circuit substrate according to the second to fourth embodiments of the invention.

### DESCRIPTION OF EMBODIMENTS

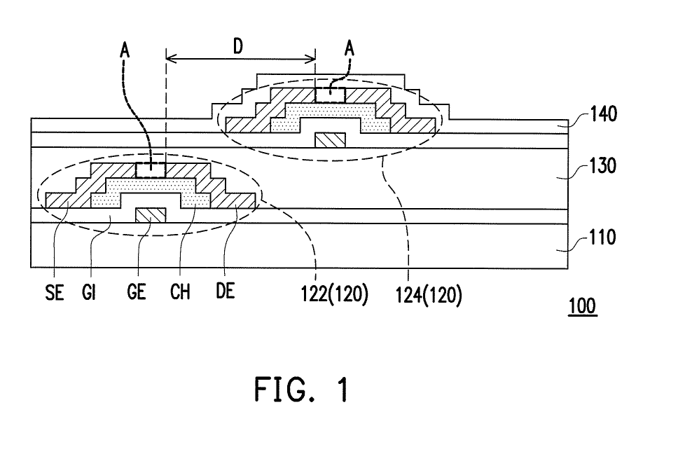

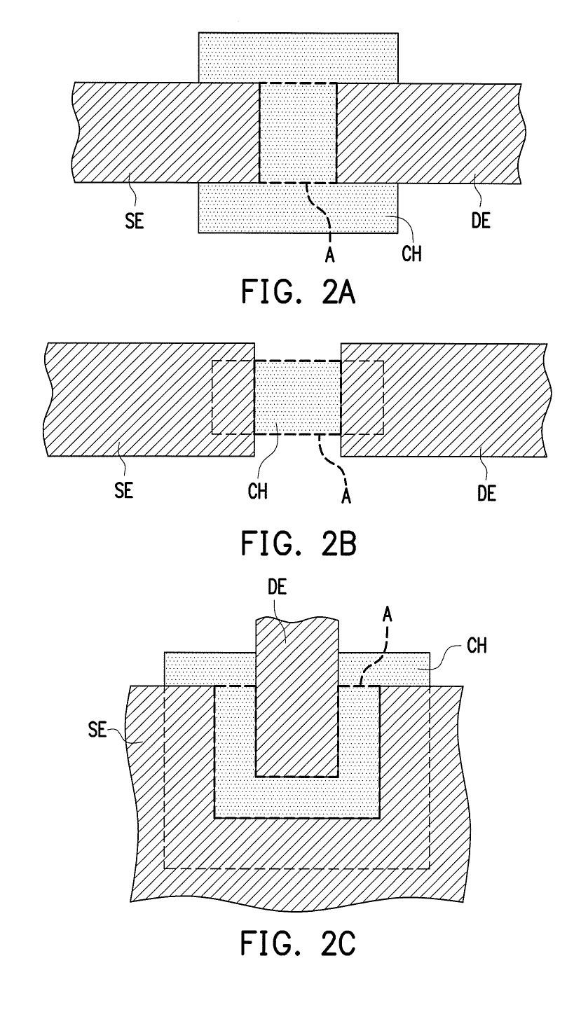

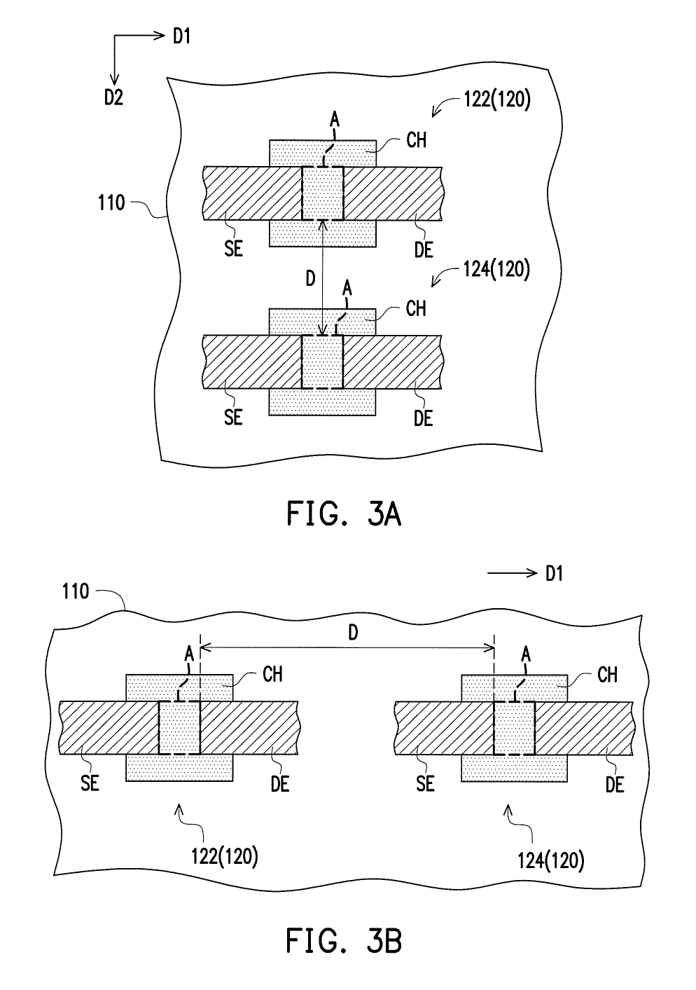

FIG. 1 is a schematic cross-section view of an active device circuit substrate according to the first embodiment of the invention. FIGS. 2A to 2C are schematic top views of three examples of relative positions of a channel layer, a source electrode and a drain electrode in FIG. 1. FIGS. 3A to 3C are schematic top views of three examples of relative positions of a first active device and a second active device in FIG. 1. Referring first to FIG. 1, an active device circuit substrate 100 includes a substrate 110, a plurality of active devices 120, and a first planarization layer 130.

The active devices 120 are disposed on the substrate 110. Each of the active devices 120 include a gate electrode GE, a channel layer CH, a source electrode SE and a drain electrode DE. In this embodiment, each of the active devices 120 is, for example, a bottom-gate TFT. More specifically, the channel layer CH is stacked with the gate electrode GE, and the channel layer CH is located, for example, above the gate electrode GE. The channel layer CH may be an oxide semiconductor layer, such as an Indium Gallium Zinc Oxide (IGZO), but the invention is not limited thereto. Each of the active devices 120 may further include a gate insulated layer GI disposed between the channel layer CH and the gate electrode GE, so as to separate the channel layer CH from the gate electrode GE.

The source electrode SE and the drain electrode DE are disposed on the channel layer CH and located on opposite sides of the channel layer CH, so as to define a channel area A of the channel layer CH. As shown in FIGS. 2A to 2C, an area of the channel area A is an area of the channel layer CH between the borders that the source electrode SE and the drain electrode DE contact the channel layer CH. After the active device is enabled, the channel area A is an area on the channel layer CH that is provided for carriers to move.

Referring again to FIG. 1, the first planarization layer 130 is disposed on the substrate 110. According to the difference in the relative positions of the active device 120 and the first planarization layer 130, the active device 120 may be divided into a first active device 122 and a second active device 124, wherein the first active device 122 is disposed between the first planarization layer 130 and the substrate 110, and the first planarization layer 130 is disposed between the first active device 122 and the second active device 124. In this embodiment, the active device 120 includes one first active device 122 and one second active device 124, but the amounts of the first active device 122 and the second active device 124 are not limited thereto. In another embodiment, the respective amounts of the first active device 122 and the second active device 124 may also be more than one.

In addition to protecting the first active device 122, the arrangement of the first planarization layer 130 further provides a flat carrying surface for the second active device 124. For instance, the first planarization layer 130 may be an organic material layer, a silicon-based material layer, a mixed layer of an organic material and a silicon-based material, or a stacked layer of at least two of the above layers. In addition, a thickness of the first planarization layer 130 may be, for example, 0.5 μm to 5 μm.

Compared with disposing all of the active devices 120 on the same plane (such as the substrate 110), the active devices 120 in this embodiment are stacked on the substrate 110 so that the active devices 120 are integrated, which reduces the space on the substrate 110 required for disposing the active devices 120 and thereby enhances the scope of application of the active devices 120, such application to an analog or logic device.

In addition, adoption of the oxide semiconductor layer as the channel layer CH of the active devices 120 in this embodiment not only provides the active devices 120 with good device property performance (i.e., high mobility), but also reduces a processing temperature required for the channel layer CH. Therefore, in addition to glass substrates having relatively higher temperature endurance, plastic substrates having relatively lower temperature endurance may also be adopted as the substrate 110. Since the plastic substrates have excellent flexibility properties, the scope of application of the active device circuit substrate 100 is broadened.

In the actual manufacturing process of the active device circuit substrate 100, the substrate 110 having obvious level difference may affect the planarization capability of the first planarization layer 130. For example, the first planarization layer 130 may be relatively bumped at a location corresponding to the first active device 122. Thereby, the device property performance or reliability of the second active device 124 disposed on the uneven first planarization layer 130 may be affected. In view of the above, by adjusting a minimum linear distance D between the channel area A of the first active device 122 and the channel area A of the second active device 124 in a direction parallel to the substrate 110, the minimum linear distance D in this embodiment is larger than or equal to 5 μm, so as to ensure that the second active device 124 is formed on a relatively flat and even area on the first planarization layer 130.

As shown in FIG. 3A, when the direction (such as a direction D1) that the source electrode SE and the drain electrode DE of the first active device 122 are arranged and the direction (such as the direction D1) that the source electrode SE and the drain electrode DE of the second active device 124 are arranged are respectively perpendicular to the direction (such as a direction D2) that the first active device 122 and the second active device 124 are arranged, the minimum linear distance D is the distance from a side of the channel area A of the first active device 122 close to the second active device 124 to a side of the channel area A of the second active device 124 close to the first active device 122.

As shown in FIG. 3B, when the direction (such as the direction D1) that the source electrode SE and the drain electrode DE of the first active device 122 are arranged and the direction (such as the direction D1) that the source electrode SE and the drain electrode DE of the second active device 124 are arranged are respectively parallel to the direction (such as the direction D1) that the first active device 122 and the second active device 124 are arranged, the minimum linear distance D is the distance from a side of the channel area A of the first active device 122 close to the second active device 124 to a side of the channel area A of the second active device 124 close to the first active device 122.

As shown in FIG. 3C, when the direction (such as the direction D1) that the source electrode SE and the drain electrode DE of the first active device 122 are arranged and the direction (such as the direction D1) that the source electrode SE and the drain electrode DE of the second active device 124 are arranged are respectively neither parallel nor perpendicular to the direction (such as a direction D3) that the first active device 122 and the second active device 124 are arranged, the minimum linear distance D is the distance from an endpoint of the channel area A of the first active device 122 close to the second active device 124 to an endpoint of the channel area A of the second active device 124 close to the first active device 122. With the different arrangements of the source electrode SE and the drain electrode DE of each of the active devices (including the first active device 122 and the second active device 124) or the different arrangements of adjacent first active device 122 and second active device 124, the minimum linear distance D may possibly be defined differently. FIGS. 3A to 3C merely show schematically three examples, but the invention is not limited thereto.

Since the location of the channel layer CH in each of the active devices 120 is where has the most intensive level difference between the active devices 120 and the substrate 110, the first active device 122 is stacked with the second active device 124 on the substrate 110 in a manner of staggered arrangement in this embodiment. Complete overlapping of the orthographic projection of the channel layer CH of the first active device 122 and the channel layer CH of the second active device 124 on the substrate 110 is avoided via the design of the minimum linear distance D. Thereby, it is avoided that the second active device 124 is formed on the relatively bumped area on the first planarization layer 130, and it is ensured that the second active device 124 is formed on a relatively flat area on the first planarization layer 130, which contributes to the reliability of the second active device 124.

In addition, the active device circuit substrate 100 of this embodiment may further include a first protective layer 140. The first protective layer 140 covers the second active device 124 so that the second active device 124 is disposed between the first protective layer 140 and the first planarization layer 130, so as to enhance reliability of the active device circuit substrate 100 and reduce negative effects of the external environment (such as moisture or oxygen) on the active device circuit substrate 100 (such as the second active device 124 and the first active device 122). For instance, the first protective layer 140 may be an inorganic material layer, such as a silicon oxide layer, a silicon nitride layer or a stacked layer of the above two layers, etc.

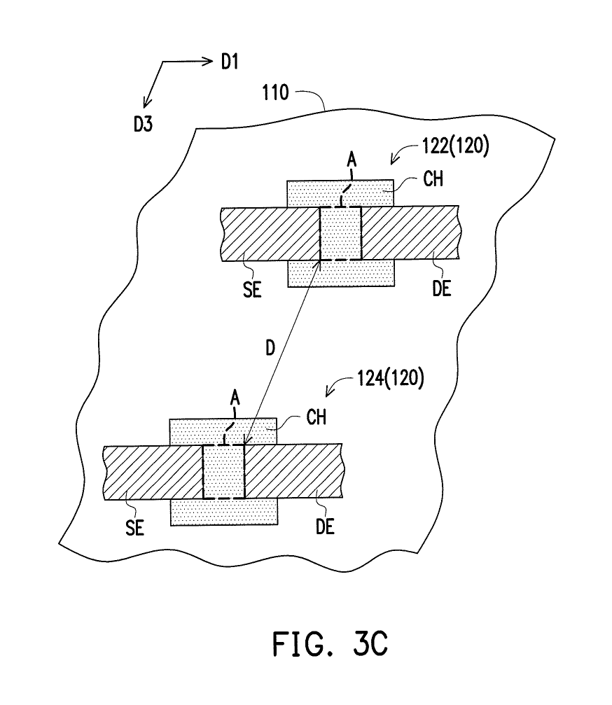

FIG. 1 illustrates merely one of the examples of the active device circuit substrate, and the invention is not limited thereto. Other implementable examples of the active device circuit substrate are described below with reference to FIGS. 4 to 6. FIGS. 4 to 6 are schematic cross-section views of an active device circuit substrate according to the second to fourth embodiments of the invention. Referring first to FIG. 4, an active device circuit substrate 200 is substantially identical with the active device circuit substrate 100 of FIG. 1, and identical devices are represented by identical numerals, and the relative positions and functions of the devices are not repeated herein. The primary difference between the active device circuit substrate 200 and the active device circuit 100 lies in that the active device circuit substrate 200 further includes a second protective layer 150. The second protective layer 150 is disposed between a first planarization layer 130A and the first active device 122 and is, for example, a continuous film for covering the first active device 122 thoroughly, while the first planarization layer 130A is disposed on the second protective layer 150. In other words, the first planarization layer 130A of this embodiment does not contact the first active device 122 directly. The second protective layer 150 is also, for example, an inorganic layer, so as to further reduce the negative effect of the external environment (such as moisture or oxygen) on the active device circuit substrate 200.

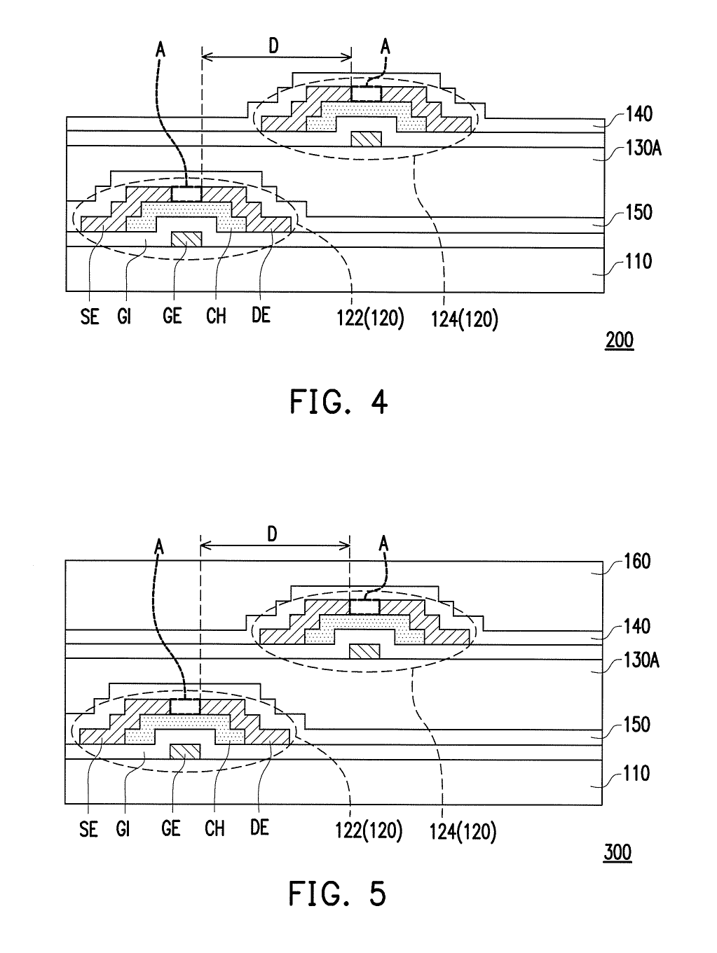

Referring to FIG. 5, an active device circuit substrate 300 is substantially identical with the active device circuit substrate 200 of FIG. 4, and identical devices are represented by identical numerals, and the relative positions and functions of the devices are not repeated herein. The primary difference between the active device circuit substrate 300 and the active device circuit 200 lies in that the active device circuit substrate 300 further includes a second planarization layer 160, wherein the first protective layer 140 is disposed between the second active device 124 and the second planarization layer 160. The material of the second planarization layer 160 may be selected from the material of the first planarization layer 130A. In another embodiment, it is also possible to dispose only the second planarization layer 160 and omit the first protective layer 140.

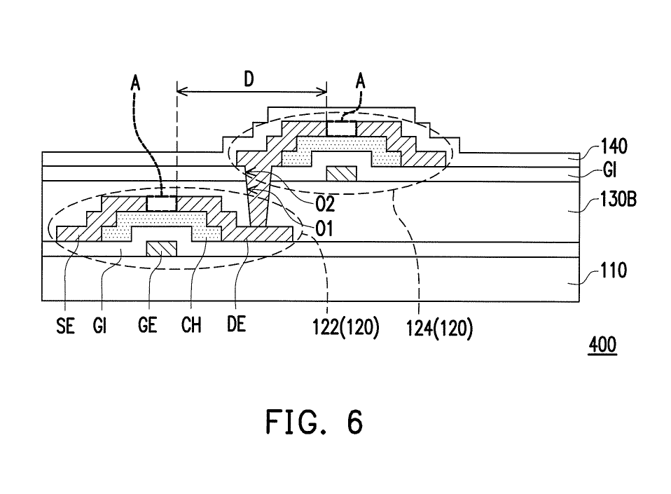

Referring to FIG. 6, an active device circuit substrate 400 is substantially identical with the active device circuit substrate 100 of FIG. 1, and identical devices are represented by identical numerals, and the relative positions and functions of the devices are not repeated herein. The primary difference between the active device circuit substrate 400 and the active device circuit substrate 100 lies in that the second active device 124 of the active device circuit substrate 100 is electrically insulated from the first active device 122 via the first planarization layer 130, while a first planarization layer 130B of the active device circuit substrate 400 includes at least one through hole O1, and the second active device 124 is electrically connected to the first active device 122 via the through hole O1. More specifically, corresponding to the through hole O1, a through hole O2 adjoining the through hole O1 is formed on the gate insulated layer GI of the second active device 124, and the source electrode SE of the second active device 124 contacts the drain electrode DE of the first active device 122 via the through holes O1 and O2. In the embodiments of FIGS. 4 to 6, with the design of the minimum horizontal distance D, it is also ensured that the second active device 124 is formed on a relatively flat area of the first planarization layers 130A or 130B, which thereby contributes to enhancing the reliability of the second active device 124.

In view of the above, integration of the active devices is facilitated by disposing the first and second active devices on opposite sides of the first planarization layer in the active device circuit substrate in the embodiments of the invention. In addition, simultaneously with the integration, it is ensured that the second active device is formed on a relatively flat area of the first planarization layer by controlling the minimum horizontal distance between the second active device and the first active device, so as to enhance the reliability of the second active device.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. An active device circuit substrate, comprising:
a substrate;
a plurality of active devices, disposed on the substrate, each of the active devices comprising a gate electrode, a channel layer, a source electrode, and a drain electrode, wherein the channel layer is stacked with the gate electrode, and the source electrode and the drain electrode are disposed on the channel layer and located on opposite sides of the channel layer, so as to define a channel area of the channel layer; and
a first planarization layer, disposed on the substrate, wherein the active devices comprise at least one first active device and at least one second active device, the at least one first active device is disposed between the first planarization layer and the substrate, and the first planarization layer is disposed between the at least one first active device and the at least one second active device, and a minimum linear distance between the channel area of the first active device and the channel area of the second active device along a direction parallel to the substrate is larger than or equal to 5 μm.

2. The active device circuit substrate of claim 1, wherein the channel layer of each of the active devices is an oxide semiconductor layer.

3. The active device circuit substrate of claim 1, wherein the first planarization layer is an organic material layer, a silicon-based material layer, a mixed layer of an organic material and a silicon-based material, or a stacked layer of at least two of the above layers.

4. The active device circuit substrate of claim 1, wherein a thickness of the first planarization layer is 0.5 μm to 5 μm.

5. The active device circuit substrate of claim 1, wherein the first planarization layer comprises at least one through hole, and the at least one second active device is electrically connected to the at least one first active device via the at least one through hole.

6. The active device circuit substrate of claim 1, wherein the at least one second active device is electrically insulated from the at least one first active device via the first planarization layer.

7. The active device circuit substrate of claim 1, further comprising:
a first protective layer, wherein the at least one second active device is disposed between the first protective layer and the first planarization layer.

8. The active device circuit substrate of claim 7, wherein the first protective layer is an inorganic material layer.

9. The active device circuit substrate of claim 7, further comprising:
a second planarization layer, wherein the first protective layer is disposed between the at least one second active device and the second planarization layer.

10. The active device circuit substrate of claim 1, further comprising:
a second protective layer, disposed between the first planarization layer and the at least one first active device.

11. The active device circuit substrate of claim 1, wherein the source electrode and the drain electrode of the first active device are arranged in a direction perpendicular to a direction that the first active device is arranged, and the source electrode and the drain electrode of the second active device are arranged in a direction perpendicular to a direction that the second active device is arranged.

12. The active device circuit substrate of claim 1, wherein the source electrode and the drain electrode of the first active device are arranged in a direction parallel to a direction that the first active device is arranged, and the source electrode and the drain electrode of the second active device are arranged in a direction parallel to a direction that the second active device is arranged.

13. The active device circuit substrate of claim 1, wherein the source electrode and the drain electrode of the first active device are arranged in a direction that is neither parallel nor perpendicular to a direction that the first active device is arranged, and the source electrode and the drain electrode of the second active device are arranged in a direction that is neither parallel nor perpendicular to a direction that the second active device is arranged.
